(19) United States
(12) Patent Application Publication
(10) Pub. No.: US 2026/0126290 A1
(43) Pub. Date: May 7, 2026

(54) DYNAMIC BIAS COMPENSATION FOR MEMS MOTION SENSORS

(71) Applicant: InvenSense, Inc., San Jose, CA (US)

(72) Inventor: Vito Avantaggiati, Milano (IT)

(21) Appl. No.: 19/374,845

(22) Filed: Oct. 30, 2025

Related U.S. Application Data
(60) Provisional application No. 63/715,600, filed on Nov. 3, 2024.

(51) Int. Cl. G01C 19/5776; G01P 15/125; H03H 17/02

(52) U.S. Cl. CPC G01C 19/5776; G01P 15/125; H03H 17/02

(57) ABSTRACT

MEMS sensors output data that may be susceptible to systematic bias that diminishes the accuracy of the data. This disclosure is directed to a method that compensates for this bias so that the output is more accurate and representative. Once a movement of the proof mass of the MEMS sensor outputs a specific characteristic signal, and that signal is identified, the signal is dynamically processed to eliminate and/or reduce the offset. Some applications may require fast settling times, high accuracy of offset removal, and robustness to vibrations and shocks. These requirements typically conflict with each other, meaning that the faster the offset removal, the lower its accuracy, and the sensor is more susceptible to errors due to vibration and shock. In order to tradeoff these requirements, the output of the MEMS sensor is filtered with some non-linear and/or time variant processing, followed by averaging the signal during a startup phase over a steadily increasing number of sampling periods. Once the startup phase is complete, the offset compensation signal is determined and removed from the initial output signal from the MEMS sensor. By utilizing the disclosed method, it is possible to maintain a high accuracy of offset estimation, a fast settling time, while also mitigating the effects of external perturbations (e.g., shocks, vibrations) on the system during the offset estimation process.

### CROSS-REFERENCE TO RELATED APPLICATION

This application claims priority to U.S. Provisional Patent Application No. 63/715,600, filed November 3, 2024, and entitled “Systems and Methods for Dynamic Bias Compensation,” which is incorporated by reference herein in its entirety for all purposes.

### BACKGROUND

Numerous items such as smart phones, smart watches, tablets, automobiles, aerial drones, appliances, aircraft, exercise aids, and game controllers may utilize sensors such as microelectromechanical system (MEMS) sensors during their operation. In many applications, various types of motion sensors such as accelerometers and gyroscopes may be analyzed independently or together in order to determine varied information for particular applications. For example, gyroscopes and accelerometers may be used in gaming applications (e.g. , smart phones or game controllers) to capture complex movements by a user, drones and other aircraft may determine orientation based on gyroscope measurements (e.g., roll, pitch, and yaw), and vehicles may utilize measurements for determining direction (e.g., for dead reckoning) and safety (e.g., to recognizing skid or roll-over conditions).

A MEMS sensor such as a MEMS accelerometer or gyroscope can have a bias (e.g., an offset) that corresponds to a non-motion output of sensor. This offset can be an inherent feature of the MEMS sensor design, can be a regular result of manufacturing processes and tolerances, and/or can be impacted in the field, based on wear, incurred stresses, temperature, or other factors. A large offset can impact measurements such as by incorrectly indicating motion or limiting bandwidth for accurate motion detection. Accordingly, techniques have been employed to identify or remove offset in MEMS sensors. These techniques are unable to quickly reach a steady state for offset removal while achieving accuracy and robustness to external shocks and vibrations.

### SUMMARY

In an embodiment of the present disclosure, a method for dynamically compensating for offset in a MEMS sensor comprises receiving an output signal based on a movement of a proof mass of the MEMS sensor in response to a force and monitoring the output signal for at least one signal characteristic, wherein the output signal is discarded until the at least one signal characteristic is identified by the monitoring (e.g., an amplitude of the output signal not exceeding a predefined limit, or the output signal derivative not exceeding a predefined limit). The method can further comprise processing, once the at least one signal characteristic has been identified, the output signal to determine an offset compensation signal that compensates an offset in the output signal. The processing can further comprise performing a first filtering of the output signal, averaging a first set of samples of the first filtered output signal over an initial sampling period of a plurality of sampling periods to generate the offset compensation signal for the initial sampling period, and increasing from the initial sampling period to a first sampling period. The processing can further comprise averaging a second set of samples of the first filtered output signal over the first sampling period to generate the offset compensation signal for the first sampling period, repeating the increasing of the sampling period during a startup phase, and averaging an additional set of samples of the first filtered output signal over each increased sampling period to generate the offset compensation signal for each increased sampling period. The processing can further comprise determining that the startup phase is complete, sampling the first filtered output signal over a fixed sampling period once the startup phase is complete to generate a plurality of fixed sample sets, and averaging each of the fixed sample sets over a fixed averaging period once the startup phase is complete to generate the offset compensation signal for each fixed averaging period, wherein the fixed averaging period is greater than or equal to a longest sampling period of the increased sampling periods, and wherein the fixed sampling period is lower than or equal to the fixed averaging period.

In an embodiment of the present disclosure, a method for removing offset from an output signal of a MEMS sensor comprises monitoring an output signal from the MEMS sensor to determine whether to start a fast offset compensation stage of operation, wherein an offset compensation signal that is used to compensate an offset in the output signal is not generated prior to the start of the fast offset compensation stage of operation. The method can further comprise generating the offset compensation signal, during the fast offset compensation stage of operation, based on an increasing sampling period and an increasing averaging period, and changing from the fast offset compensation stage of operation to a first slow offset compensation stage of operation. The method can further comprise generating the offset compensation signal, during the first slow offset compensation stage of operation, based on a first fixed sampling period and a first fixed averaging period, changing from the first slow offset compensation stage of operation to a second slow offset compensation stage of operation, and generating the offset compensation signal, during the second slow offset compensation stage of operation, based on a second fixed sampling period and a second fixed averaging period, wherein the second fixed averaging period is different than the first fixed averaging period.

In an embodiment of the present disclosure, a system for removing offset from a MEMS sensor comprises amplitude limiting circuitry coupled to receive the output signal from the MEMS sensor and to limit an amplitude of the output signal to output an amplitude-limited signal and a filter coupled to the amplitude limiting circuitry to receive the amplitude-limited signal, wherein the filter removes a samples that are not within a pass band of the filter to output a filtered signal. The system can further comprise averaging circuitry coupled to the filter to receive the filtered signal, wherein the averaging circuitry outputs an averaged signal based on a sampling period and an averaging period, processing circuitry coupled to the averaging circuitry to process the averaged signal to generate an offset compensation signal that is suitable for removing the offset from the output signal, and a bandwidth controller configured to modify a bandwidth of the filter, the sampling period, and the averaging period, wherein each of the bandwidth, the sampling period, and the averaging period are modified during an initial fast offset compensation stage of operation, and wherein the bandwidth, the sampling period, and the averaging period become fixed during at least a portion of a slow offset compensation stage that occurs after completion of the initial fast offset compensation stage.

### BRIEF DESCRIPTION OF DRAWINGS

The above and other features of the present disclosure, its nature, and various advantages will be more apparent upon consideration of the following detailed description, taken in conjunction with the accompanying drawings in which:

FIG. 1 shows an illustrative MEMS system in accordance with an embodiment of the present disclosure;

FIG. 2 depicts an exemplary diagram of a MEMS inertial sensor including dynamic bias compensation in accordance with an embodiment of the present disclosure;

FIG. 3 depicts an exemplary timing diagram including an initiation and completion of a startup phase in accordance with an embodiment of the present disclosure;

FIG. 4 depicts an exemplary timing diagram of dynamic bias compensation in accordance with an embodiment of the present disclosure;

FIG. 5 depicts exemplary steps for performing dynamic bias compensation in accordance with an embodiment of the present disclosure; and

FIG. 6 depicts exemplary steps of a startup phase and a fast offset compensation phase of dynamic bias compensation in accordance with an embodiment of the present disclosure.

### DETAILED DESCRIPTION

A MEMS sensor such as a MEMS accelerometer (e.g., to measure linear acceleration) or gyroscope (e.g., to measure angular velocity) may have an internal bias corresponding to a portion of the sensor output signal that includes an offset that is unrelated to the underlying physical phenomenon being measured (e.g., linear acceleration). The cause of the offset can be varied, and can be a characteristic of the MEMS sensor as manufactured (e.g., due to design features, manufacturing tolerances, etc.), the end-use device the MEMS sensor is installed with (e.g., due to assembly with other components, stresses within systems, etc.), the operation of the MEMS sensor over time (e.g., due to typical wear and tear), operational and environmental conditions (e.g., electrical signal quality, temperature, etc.), and other causes. Further, different end-use applications have different needs in terms of startup time and relevant signal characteristics to be measured (e.g., linear acceleration or Coriolis force at particular frequencies of interest in a vehicle end-use application).

In accordance with the present disclosure, a dynamic bias compensation system includes circuitry for performing a variety of functions useful to generating an accurate offset compensation signal under a variety of different operating conditions. Shock rejection circuitry monitors a received output signal from the MEMS sensor to identify and reject shock forces that should not be considered during the determination of the offset compensation signal. Vibration rejection circuitry monitors the received output signal from the MEMS sensor to identify and reject vibration forces that should not be considered during the determination of the offset compensation signal. Averaging circuitry analyzes the output signal over time, effectively removing the force of interest (e.g., linear acceleration) from the output signal such that the averaged result generally corresponds to the offset to be removed from the output signal. The sampling period and the averaging period of the averaging circuitry can be modified as appropriate based on particular operational requirements, e.g. to shorten the settling time of the bias compensation. Additional circuitry and filters (e.g., low pass, band pass, or high pass) prepare the averaged signal as an offset compensation signal to be removed from the output signal.

The operations of components of the dynamic bias compensation system are modifiable, for example, to control and modify filter bandwidths, amplitude limits, sampling periods, and averaging periods, based on particular operational requirements, e.g. to shorten the settling time of the bias compensation. During an initial startup of the MEMS sensor, initial samples can be discarded until a condition corresponding to a likelihood of useful output signal samples occurs. Once processing of the output signal for offset purposes begins, the offset can be determined in a fast offset compensation mode, during which sampling periods, averaging periods, and other system parameters such as filter bandwidths and rate limitations are initially set to more quickly provide a useful offset compensation signal during initial sensor operation. The sampling periods and averaging periods – and thus the accuracy of the offset compensation signal – can be modified during this fast offset compensation mode, while other system parameters are also updated as more data is received. Once the initial fast offset compensation mode is complete, a slow offset compensation mode can be initiated. In some implementations, the slow offset compensation mode can include continued modifications to system parameters until the offset value, and the respective operations of the dynamic bias compensation system components, settle into a steady state.

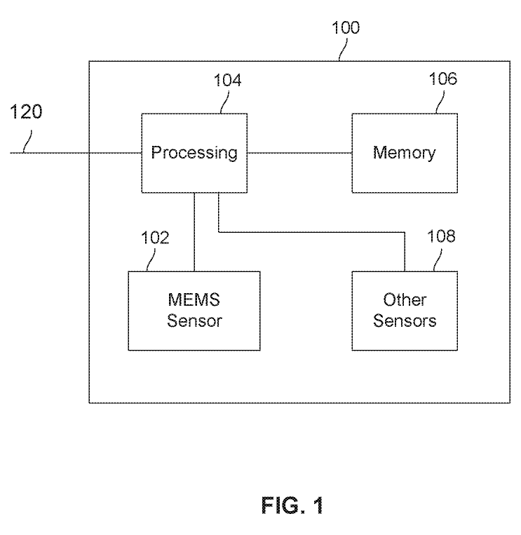

FIG. 1 shows an illustrative MEMS system 100 in accordance with an embodiment of the present disclosure. Although particular components are depicted in FIG. 1, it will be understood that other suitable combinations of MEMS sensors, processing components, memory, and other circuitry may be utilized as necessary for different applications and systems. In accordance with the present disclosure, the MEMS system may include a MEMS sensor 102 (e.g., a MEMS inertial sensor such as a MEMS accelerometer or MEMS gyroscope) as well as additional MEMS sensors 108. Although the present disclosure will be described in the context of signals received from certain MEMS sensors, it will be understood that the dynamic bias compensation method (and any pertinent components) of the present disclosure may be utilized with other MEMS components and applications.

Processing circuitry 104 may include one or more components providing processing based on the requirements of the MEMS system 100. In some embodiments, processing circuitry 104 may include hardware control logic that may be integrated within a chip of a sensor (e.g., on a base substrate of a MEMS sensor 102 or other sensors 108, or on an adjacent portion of a chip to the MEMS sensor 102 or other sensors 108) to control the operation of the MEMS sensor 102 or other sensors 108 and perform aspects of processing for the MEMS sensor 102 or the other sensors 108. In some embodiments, the MEMS sensor 102 and other sensors 108 may include one or more registers that allow aspects of the operation of hardware control logic to be modified (e.g., by modifying a value of a register). In some embodiments, processing circuitry 104 may also include a processor such as a microprocessor that executes software instructions, e.g., that are stored in memory 106. The microprocessor may control the operation of the MEMS sensor 102 by interacting with the hardware control logic and processing signals received from MEMS sensor 102. The microprocessor may interact with other sensors 108 in a similar manner. In some embodiments, some or all of the functions of the processing circuitry 104, and in some embodiments, of memory 106, may be implemented on an application specific integrated circuit (“ASIC”) and/or a field programmable gate array (“FPGA”).

Although in some embodiments (not depicted in FIG. 1), the MEMS sensor 102 or other sensors 108 may communicate directly with external circuitry (e.g., via a serial bus or direct connection to sensor outputs and control inputs), in an embodiment the processing circuitry 104 may process data received from the MEMS sensor 102 and other sensors 108 and communicate with external components via a communication interface 110 (e.g., a serial peripheral interface (SPI) or I2C bus, in automotive applications a controller area network (CAN) or Local Interconnect Network (LIN) bus, or in other applications a suitably wired or wireless communications interface as is known in the art). The processing circuitry 104 may convert signals received from the MEMS sensor 102 and other sensors 108 into appropriate measurement units (e.g., based on settings provided by other computing units communicating over the communication interface 110) and perform more complex processing to determine measurements such as orientation or Euler angles, and in some embodiments, to determine from sensor data whether a particular activity (e.g., walking, running, braking, skidding, rolling, crashes, etc.) is taking place. In some embodiments, some or all of the conversions or calculations may take place on the hardware control logic or other on-chip processing of the MEMS sensor 102 or other sensors 108.

In some embodiments, certain types of information may be determined based on data from multiple MEMS sensors 102 and other sensors 108 in a process that may be referred to as sensor fusion. By combining information from a variety of sensors it may be possible to accurately determine information that is useful in a variety of applications, such as image stabilization, navigation systems, automotive controls and safety, crash detection, dead reckoning, remote control and gaming devices, activity sensors, 3-dimenstional cameras, industrial automation, and numerous other applications.

In embodiments of the present disclosure, the MEMS sensor 102 may function within devices that are sensitive to external perturbations (e.g., shocks, vibrations) such as in vehicles. To achieve efficient functionality levels for the MEMS sensors 102 within applications where safety can be a concern, the implementation of new strategies and methods may be required. Bias (e.g., offsets) corresponding to a portion of a measured output signal that does not correspond to the actual physical activity being measured may be present in a MEMS sensor such as MEMS sensor 102. These offsets can be inherent in manufacturing tolerances, can be caused by installation or combination with other devices in an end use application, can drift over time due to usage such as normal wear, may be impacted both temporarily and over time by environmental factors such as temperature, as well as myriad other causes. Removal of these offsets within MEMS sensors such as a MEMS sensor 102 ensures that the output is as representative and as accurate as possible. While static bias compensation techniques may be employed, their drawbacks (e.g., bias drift over time) preclude them from being utilized in certain critical applications such as in vehicle sensors. Conventional dynamic bias compensation techniques are unable to provide accurate sensing at desired frequencies during an initial startup period and are susceptible to incorrectly including external forces such as shocks and vibration having frequency content close to the offset frequency (e.g., an offset at a lower frequency than a desired frequency to be sensed in a vehicle application).

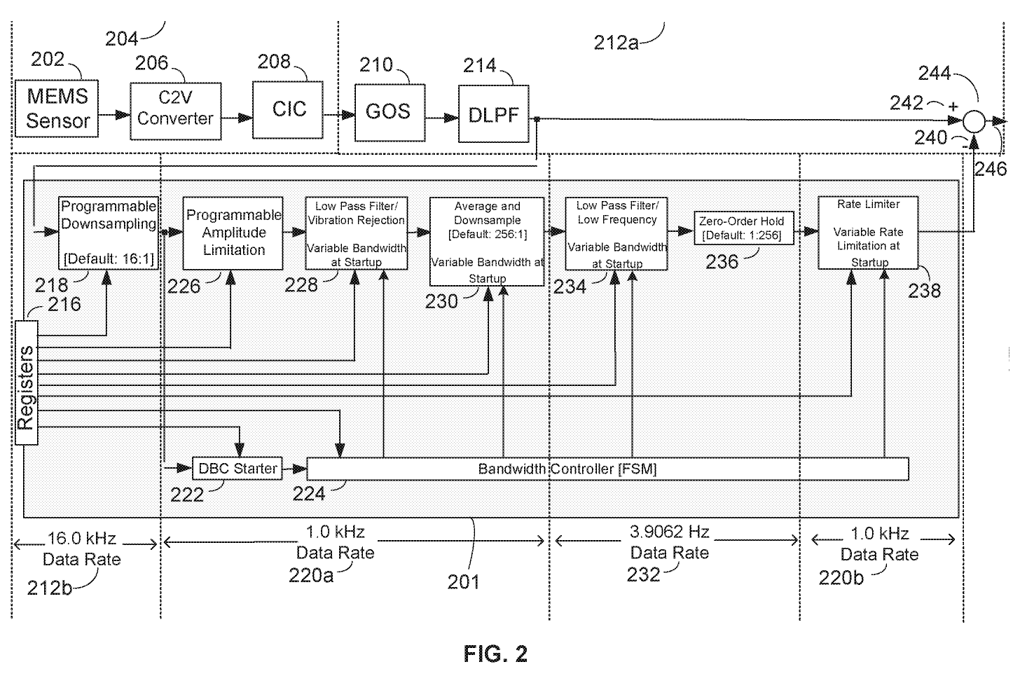

FIG. 2 depicts an exemplary diagram of a MEMS inertial sensor (e.g., a MEMS accelerometer or MEMS gyroscope) including dynamic bias compensation in accordance with an embodiment of the present disclosure. Although FIG. 2 (and other figures) will be described in the context of a particular application and system components, it will be understood that the present disclosure may be utilized with a variety of other devices (e.g., other types of MEMS sensors), and that specific components and data rates described herein are exemplary only, and that a variety of data rates and components can be added, removed, substituted, or modified in accordance with the present disclosure. In the exemplary embodiment of FIG. 2, a dynamic bias compensation (DBC) system 201 is used to determine offset from an output signal of a MEMS sensor 202 that in turn is removed from the output signal (e.g., after certain additional processing at) at subtractor 244.

The output of the MEMS sensor 202 is a capacitance which in turn is based on a location and movement of one or more proof masses relative to one or more electrodes (e.g., based on a linear acceleration along a certain direction). This output includes both a signal of interest based on the movement of the proof mass due to the force being measured but may also include a bias (e.g., offset) signal portion which is not representative of the force being measured. The capacitance is converted into an electrical signal (e.g., a charge) for further processing such as via a capacitance-to-voltage (C2V) converter 206. A cascaded integrator-comb (CIC) 208 filters the signal and reduces a first data rate 204 to a second data rate 212a, 212b. The signal passes through a gain and offset scaling (GOS) circuitry 210, followed by a digital low pass filter (DLPF) 214 that removes high frequencies, (e.g., above a frequency of interest for the particular application). The output of the digital low pass filter corresponds an “output signal” of the MEMS sensor 202, i.e., is the signal that is evaluated for determining offset by DBC system 201 and that is provided to the subtractor 244 to have offset removed. It will be understood that this output signal may undergo additional processing operations before being provided to the subtractor 244 and will still correspond to the MEMS sensor 202 output signal as described herein.

DBC system 201 includes registers 216 are used to set particular parameters of various components of the DBC system 201, while a bandwidth controller 224 is able to change the output data rate of selected components. The output signal from the DLPF 214 enters the programmable downsampling circuitry 218 that further reduces the second data rate 212a, 212b to a third data rate 220a, 220b. When the DBC starter 222 detects a particular output signal characteristic (or plurality of particular output signal characteristics), it sends a trigger signal to the bandwidth controller 224 to begin a fast offset compensation process. The output signal passes through a programmable amplitude limitation circuitry 226 and then through a low pass filter 228, which have parameters based on the values of the registers 216 and the particular stage of operation as described herein. The signal is averaged and further downsampled by average and downsampler 230 to a fourth data rate 232 to provide a first offset measure. Another low pass filter 234 removes higher frequency errors from the first offset measure, and zero-order hold circuitry 236 increases the data rate back to the third data rate 220a, 220b. Although described as low pass filters herein, in some implementations other filter types such as band pass or high pass filters may be utilized. A rate limiter 238 adjusts the offset compensation signal 240 such that the offset compensation signal 240 does not change by more than a predetermined rate. Then a subtractor 244 subtracts the measured offset compensation signal 240 from the original output signal 242 to generate an acceleration signal 246. This acceleration signal 246 is more accurate and representative than the original output signal 242.

The MEMS sensor 202 may be a single device or any number of MEMS sensors. For example, the MEMS sensor 202 may be a single MEMS inertial sensor, group of MEMS inertial sensors, combinations of different types of MEMS sensors, or any combination thereof. For example, multiple sensors may be processed by a single set of processing circuitry by being selectively provided to the processing circuitry such as by time multiplexing the signals in a round-robin fashion (not depicted). The movement of the proof masses of the MEMS sensor is dependent on the configuration of the MEMS sensor 202, the direction of the applied force, and how the MEMS sensor 202 is positioned. The movement of the proof mass and the generated output from the MEMS sensor 202 may be determined using one or more sensors that are capable of measuring changes in a particular value (e.g., capacitance, inductance, resistance). The output signal of the MEMS sensor 202 first proceeds through a C2V converter 206.

A C2V converter 206 converts a capacitance value from the MEMS sensor 202 into a voltage value. The input range of the C2V converter 206 is such that it can accommodate the full range of measured output signals from the MEMS sensor 202. The gain of the C2V converter 206 may be variable. The voltage output from the C2V converter 206 may be linear or non-linear. The output signal from the C2V converter 206 passes next through a cascaded integrator-comb (CIC) 208.

The cascaded integrator-comb (CIC) 208 acts as a decimation filter. The decimation factor may vary between CICs 208 and may be different depending on the specific MEMS sensor 202 that is generating the output signal. The number of stages within the CIC 208 to reduce the first data rate 204 to a second data rate 212a, 212b (e.g., 16 kHz) may be any number such that the desirable second data rate can be achieved. The output signal (at a second data rate 212a, 212b) from the CIC 208 passes next through a gain and offset scaling (GOS) circuitry 210, which processes the output signal to apply gain and scaling to optimize the output signal for further process. The output signal from the GOS circuitry 210 passes next through a digital low pass filter 214.

The digital low pass filter (DLPF) 214 suppresses high frequencies within the output signal, while also smoothing the output signal. The cutoff frequency of the DLPF 214 can be any value to remove unwanted high frequencies within the output signal, e.g., greater than a frequency of interest for the particular application. The output signal from the DLPF 214 serves as the original output signal 242 for the subtractor 244, as well as an input signal to the programmable downsampling circuitry 218 within the DBC system 201.

Within the DBC system 201 are registers 216 that can be used to control the presets and particular characteristics of various components within the DBC system 201. The registers 216 may be used to control characteristics such as bandwidths, calibration values, test values, output data rates, and frequency ranges. Both digital and analog portions of the DBC system 201may be configured using the registers 216. Other circuits associated with the DBC system 201 may also be configured using the registers 216. In the embodiment depicted in FIG. 2, the registers 216 are able to control characteristics of the programmable downsampling circuitry 218, DBC starter 222, bandwidth controller 224, programmable amplitude limitation circuitry 226, low pass filter 228, average and downsampler 230, low pass filter 234, and rate limiter 238. Each component that the registers 216 can configure may be configured independently or dependently from the other components.

The programmable downsampler 218 further reduces the data rate from a second data rate 212a, 212b to a third data rate 220a, 220b. The programmable downsampler 218 may be programmed, for example using the registers 216, to reduce the data rate at a specified decimation ratio on default (e.g., 16:1 reduction). The decimation ratio may be constant or dynamic before, during, and/or after the output signal is generated by the MEMS sensor 202. The decimation ratio may have values such as 1:1, 2:1, 4:1, 8:1, 16:1, 32:1, 64:1, 128:1, or any other N:1 decimation ratio. For example, if the second data rate 212a, 212b was 16 kHz and the programmable downsampler 218 had a decimation ratio of 16:1, then the third data rate 220a, 220b would be 1 kHz. The output signal from the DLPF 214 is not further processed at this step (i.e., only data rate is reduced). The output signal (at a third data rate 220a, 220b) from the programmable downsampler 218 passes next through a programmable amplitude limitation circuitry 226.

The DBC starter 222 dictates when the dynamic offset estimation process can be initiated, e.g., initially for a fast offset compensation stage. The DBC starter 222 may be programmed using the registers 216. The set parameters of the DBC starter 222 may be constant or dynamic before, during, and/or after the output signal is generated by the MEMS sensor 202. The DBC starter 222 determines when signals received at the DBC system 201 are initially processed to determine an offset. This processing avoids generating offset compensation signals that are inaccurate during the initial startup phase of DBC system 201. Depending on the dynamic behavior and particular characteristics (e.g., amplitude, frequency, change in amplitude, etc.) of the initial signal samples, the dynamic offset estimation process may or may not be in initiated. For example, if the amplitude, or the change in amplitude, of the first initial signal samples is outside a predefined limit that is pre-programmed into the DBC starter 222, the DBC starter 222 would discharge those samples before initiating the dynamic offset estimation process (thus preventing the filters and other components within the DBC system 201 from generating an offset compensation signal based on these initial samples). The amount and/or duration of discharge can be time-based (e.g., 50 ms), signal characteristic-based (e.g., amplitude threshold), signal amount-based (e.g., 50 signal samples), or any other parameter or combination of parameters such that the DBC system 201 can still operate within its functional bounds. Multiple conditions may need to be met before the initial signal samples are processed by the DBC system 201, such as requiring two consecutive signal samples to satisfy a particular amplitude and that their difference is such to satisfy a particular value. Generally, the discharging of data should last no longer than 50 ms (after which the output signal samples will be processed by the DBC system 201). Once the programmed conditions are met, the DBC starter 222 sends a trigger signal to the bandwidth controller 224, which in turn permits the DBC system 201 to initiate the processing of the output sample signals.

The bandwidth controller 224 receives the trigger signal from the DBC starter 222, which prompts the circuitry to start permitting output signals from the MEMS sensor 202 to be processed by the DBC system 201. Components within the DBC system 201 can have some of their characteristics modified by the bandwidth controller 224. In the embodiment depicted in FIG. 2, the bandwidth controller 224 can modify characteristics of the low pass filter 228, average and downsampler 230, low pass filter 234, and the rate limiter 238. In other embodiments, the bandwidth controller 224 may modify characteristics of fewer or additional components of the DBC system 201, or modify characteristics of associated or supplementary circuits outside the DBC system 201. The characteristics of the components connected to the bandwidth controller 224 may be modified independently or dependently of one another.

The output signal from the programmable downsampler 218 serves as an input signal to the programmable amplitude limitation circuitry 226, which modulates high amplitude signals such as due to system “shocks” (e.g., a short pulse signal comprising high amplitude and high power characteristics) before potentially being processed by the DBC system 201. The amplitude threshold may be predefined by registers 216 before the output signal is generated by the MEMS sensor 202, or it may be dynamically defined during and/or after the output signal is generated by the MEMS sensor 202. The amplitude limitation circuitry 226 may have multiple modes of operation. For example, a cancel mode may outright block sample signals (e.g., set sample signal to zero), a limitation or clamping mode may clip the sample signal to the threshold value, and a disabled mode may apply no limitation to sample signals (i.e., no modulation of any sample signal by the amplitude limitation circuitry 226). The mode of operation may be static or dynamic (e.g., triggered if potential conditions are met or during certain stages of operation of the DBC system 201). The output signal from the programmable amplitude limitation circuitry 226 passes next to the low pass filter 228.

The low pass filter 228 functions as an anti-vibration filter. Vibrations that are not due to the force of interest may occur throughout operation but in some implementations may be particularly likely during the MEMS sensor startup time, which for example may correspond with the startup of a vehicle. Vibrations may be reduced or removed before they proceed further through the DBC system 201. The cutoff frequency of the low pass filter 228 can be an appropriate value to remove unwanted frequencies within the output signal, for example, based on the particular end-use application. The cutoff may be predefined by registers 216 before the output signal is generated by the MEMS sensor 202, and/or it may be dynamically defined during and/or after the output signal is generated by the MEMS sensor 202. Each low pass filter 228 may have its own rate of roll-off and latency. The low pass filter 228 may have multiple modes of operation. For example, a bypass/disable mode that may apply no filtering to the sample signals. The mode of operation may be static or dynamic (e.g., triggered if potential conditions are met). Properties (e.g., cutoff frequency, activation) of the low pass filter 228 may be modified in real time (i.e., after the MEMS sensor 202 outputs a signal) to more effectively modulate the output signal. The bandwidth controller 224 may modify selected characteristics (e.g., bandwidth) of the low pass filter 228 during processing within the DBC system 201, for example, based on a particular operating mode of the DBC system 201. In some embodiments, the low pass filter 228 may have a middle-low bandwidth and it may be variable. The low pass filter 228 only starts operating when the DBC starter 222 sends the trigger signal to the bandwidth controller 224 that in turn sends a signal to the low pass filter 228. The output signal from the low pass filter 228 passes next to the average and downsampler 230.

The average and downsampler 230 averages a set of samples received during a sampling period, and averages those signals over an averaging period. The offset can generally be identified by averaging the received samples over an appropriate time period, since while the offset may change over time and under different operating conditions, it generally will not dramatically change dynamically during operation. Further, the offset should typically have a low frequency (e.g., baseband). As described herein, the sampling period and averaging period can be dynamically modified during operation to properly balance the manner of determining the offset for the particular operating stage of the MEMS sensor. For example, the averaging can initially be performed over a smaller number of samples during an initial fast offset compensation stage, in which it is desired to provide an offset estimation during initial operation. During this fast offset compensation stage, the sampling period and averaging period can iteratively increase as described herein. As additional samples are acquired over time the sampling period and/or averaging period can continue to change (e.g., increase) until the fast offset compensation is complete, and in some embodiments, followed by further stages of modifying one or both of the sampling period and/or averaging period. In some embodiments, the additional stages can be slow offset compensation stages in which the sampling period and averaging periods are fixed. During some stages of operation, the sampling period and the averaging period can be the same, i.e., the averaging is performed as samples are received. In some stages of operation (e.g., during later stages of slow offset compensation) the averaging period can be longer (e.g., an integer multiple) of the sampling period to average more samples. In this manner, initial offset values can be provided soon after sensor startup with a relatively high accuracy (e.g., based at least in part on the amplitude and vibration limitation of amplitude limitation circuitry 226 and low pass filter 228 removing transients and noise), with accuracy improving as more samples are acquired and the offset generally settles, as described herein.

The average and downsampler 230 also further reduces the data rate from a third data rate 220a, 220b to a fourth data rate 232 based on the averaging period. The average and downsampler 230 may be programmed, for example using the registers 216, to reduce the data rate at a specified decimation ratio on default (e.g., 256:1 reduction). For example, if the third data rate 220a, 220b was 1 kHz and the average and downsampler 230 had a decimation ratio of 256:1, then the fourth data rate 232 would be 3.9062 Hz. The average and downsampler 230 may have multiple modes of operation. For example, a single average mode that may calculate the averages of the sample signals and implements a decimation factor equivalent to the inverse of the average number of sample signals. The mode of operation may be static or dynamic (e.g., triggered if potential conditions are met). The bandwidth controller 224 may modify selected characteristics (e.g., bandwidth) of the average and downsampler 230 during processing within the DBC system 201. For example, the bandwidth may be variable at the start of the process, but become more constant as the dynamic offset estimation process comes closer to terminating. The output signal (at a fourth data rate 232) from the average and downsampler 230 passes next through a low pass filter 234.

The low pass filter 234 refines the offset estimation output by the average and downsampler 230. The cutoff frequency of the low pass filter 234 can be any value to remove errors or disturbances in the offset estimation that may occur at unwanted frequencies within the output signal, but is generally a narrow filter range. The cutoff may be predefined by registers 216 or may be dynamically defined during operation. The low pass filter 234 may have multiple modes of operation. For example, a bypass/disable mode that may apply no filtering to the averaged output. The mode of operation may be static or dynamic (e.g., triggered if potential conditions are met). Properties (e.g., cutoff frequency, activation) of the low pass filter 234 may be modified in real time to more effectively modulate the output signal. The bandwidth controller 224 may modify some of the characteristics (e.g., bandwidth and cut-off frequency) of the low pass filter 234 during processing within the DBC system 201. The output signal from the low pass filter 234 passes next to the zero-order hold circuitry 236.

The zero-order hold circuitry 236 serves to increase the data rate of the output signal. The input to the zero-order hold circuitry 236 is at a fourth data rate 232, but the output from the zero-order hold circuitry 236 is back at the third data rate 220a, 220b. In some embodiments, the particular characteristics of the zero-order hold circuitry 236 may be modifiable and programmable by registers 216 (or by additional circuitry). The interpolation ratio (i.e., upsampling ratio) of the zero-order hold circuitry 236 may be simultaneously set to inversely correspond to the decimation ratio of the average and downsampler 230. The interpolation ratio may be constant or dynamic before, during, and/or after the output signal is generated by the MEMS sensor 202. The interpolation ratio (e.g., 1:256 upsample) of the zero-order hold circuitry 236 should be controlled such that the data rate of the output from the zero-order hold circuitry 236 matches the data rate of the input to the average and downsampler 230. For example, if the fourth data rate 232 (i.e., input to the zero-order hold circuitry 236) was 3.9062 Hz and the zero-order hold circuitry 236 had an interpolation ratio of 1:256, then the output data rate would be 1 kHz. The output signal from the zero-order hold circuitry 236 passes next to the rate limiter 238.

The rate limiter 238 serves to limiting the rate of change (e.g., not too rapidly). The rate limiter 238 functions similar to an operating slew rate by setting a maximum rate of change and ensuring the output signal does not surpass that maximum value. For example, if the value of an output signal is 1, and the following output signals are 100, but the rate limiter only allows for a maximum change of 10, then the output signal will slowly ramp up the output value from 1 to 100 (in increments of 10). In some embodiments, the rate limiter 238 may limit the rate of change by executing an algorithm (e.g., calculating a derivative of the sample signal, or simply the difference between one sample and the previous one). The default rate of change limit may be predefined by registers 216 and/or it may be dynamically defined during operation. The bandwidth controller 224 may modify some of the characteristics (e.g., ramp rate) of the rate limiter 238 during processing within the DBC system 201. The rate limiter 238 may have multiple modes of operation. For example, an automatic mode whereby the bandwidth controller 224 automatically calculates and updates parameters of the algorithm within the rate limiter 238. The mode of operation may be static or dynamic (e.g., triggered if potential conditions are met). The input to the rate limiter 238 is at a third data rate 220a, 220b, but the output from the rate limiter 238 is back at the second data rate 212a, 212b (e.g., 16.0 kHz). The output signal (at the second data rate 212a, 212b) from the rate limiter 238 is the offset compensation signal 240 and is provided to subtractor 244.

The subtractor 244 subtracts the offset compensation signal 240 (outputted from the DBC system 201) from the output signal 242 to generate an acceleration signal 246. Note that the offset compensation signal 240 and the original output signal 242 are to have the same data rate (e.g., second data rate 212a, 2122b) before the subtractor 244 performs any operations. The acceleration signal 246 has a data rate (e.g., second data rate 212a, 212b) that is equivalent to the data rates of both the offset compensation signal 240 and the original output signal 242. The acceleration signal 246 is a more accurate and representative value (i.e., lacking significant bias from the sensor) of the real-world measurements that the MEMS sensor 202 senses.

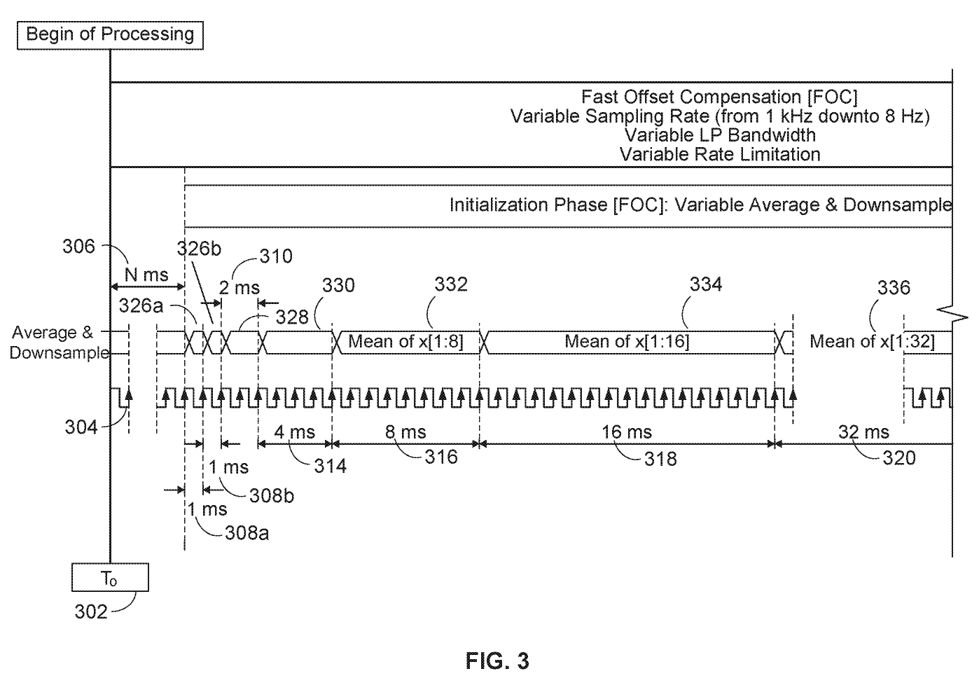

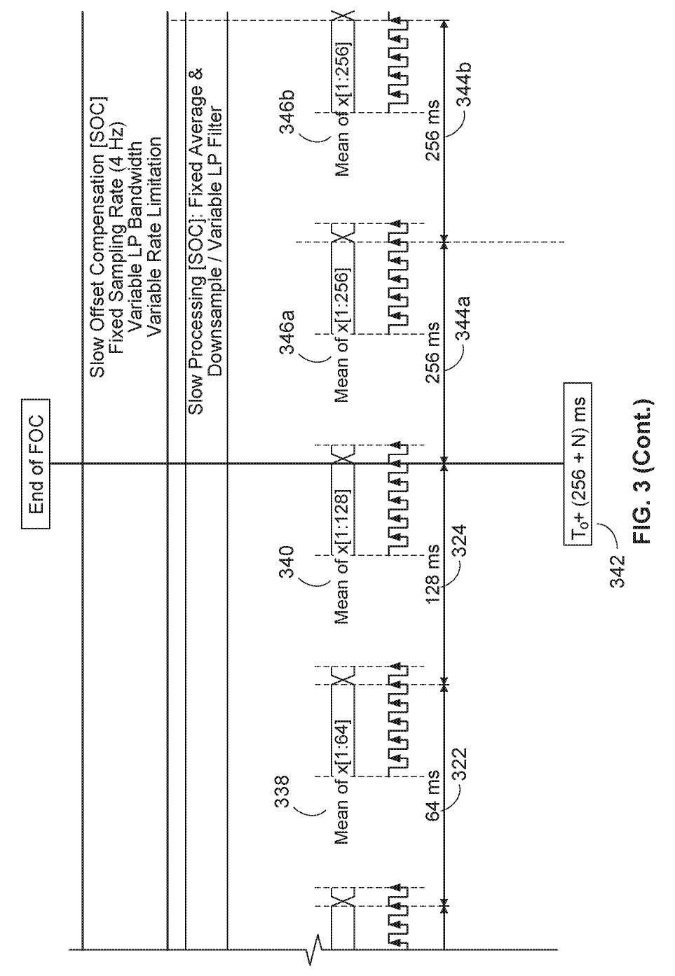

FIG. 3 depicts an exemplary timing diagram including an initiation and completion of a startup phase in accordance with an embodiment of the present disclosure. The fast offset compensation (FOC) begins at a starting time (Tₒ) 302. The output signal 304 from the MEMS sensor may have an initial discharge time 306. The output signal 304 is averaged at set periods of time during FOC. For example, an average signal 326a, 326b is generated after a sampling period of 1 ms 308a, an average signal 328 is generated after a sampling period of 2 ms 310, an average signal 330 is generated after a sampling period of 4 ms 314, an average signal 332 is generated after a sampling period of 8 ms 316, an average signal 334 is generated after a sampling period of 16 ms 318, an average signal 336 is generated after a sampling period of 32 ms 320, an average signal 338 is generated after a sampling period of 64 ms 322, and an average signal 340 is generated after a sampling period of 128 ms 324. The FOC processing of the output signal 304 is finished at completion time 342. Afterwards, the output signal 304 enters Phase A of the slow offset compensation (SOC) to begin processing whereby the sampling periods between signal averaging remain constant (i.e., a fixed sampling rate is utilized). For example, an average signal 346a, 346b is generated after a sampling period of 256 ms 344a, 344b.

The FOC process begins at starting time 302, which is when the MEMS sensor generates output signal 304. After the starting time 302, there may be an initial discharge time 306 that occurs. If the first output signal 304 (or plurality of output signals 304) from the MEMS sensor is erratic or too dynamic, then it may be desirable to discharge some of that initial data before initiating the FOC process. For example, if the output signal 304 is not within predefined limits of amplitude and signal derivative, then a discharge time 306 may be implemented to allow time for a less dynamic signal to be outputted by the MEMS sensor. The decision to discharge or not may be programmed within a particular register interface within the FOC circuit. Particular conditions may need to be met before the discharge time 306 is completed, such as two consecutive output signals 304 having a characteristic amplitude. In an embodiment, the discharge time 306 has a limit of 50 ms, which corresponds to known characteristics of the sensor and/or end use application and a corresponding expected time after which usable data is received from the MEMS sensor. Once the discharge time 306 is complete, the output signal 304 continues with the averaging steps within the FOC process.

The output signal 304 from the MEMS sensor is averaged during set sampling periods. The duration (D) of these sampling periods generally follows the formula: D = 2^{t}, where “D” is the duration in milliseconds and “t” is any positive whole number. In an embodiment, the duration (D) has a maximum value of 128 during the FOC process, but in some embodiments this maximum value may be larger. Therefore, the duration of these sampling periods in the depicted example follows the pattern: 1 ms, 2 ms, 4 ms, 8 ms, 16 ms, 32 ms, 64 ms, 128 ms. In the embodiment depicted in FIG. 3, the duration of these sampling periods within the FOC process follows this pattern such that there is a 1 ms sampling period 308a, 308b, a 2 ms sampling period 310, a 4 ms sampling period 314, an 8 ms sampling period 316, a 16 ms sampling period 318, a 32 ms sampling period 320, a 64 ms sampling period 322, and a 128 ms sampling period 324. During each of these sampling period durations, the output samples 304 are processed by DBC system to generate an offset compensation signal that in turn is based on processing and then averaging a set of received samples over an averaging period. In the embodiment depicted in FIG. 3, an average signal 326a, 326b is generated after a sampling period of 1 ms 308a, an average signal 328 is generated after a sampling period of 2 ms 310, an average signal 330 is generated after a sampling period of 4 ms 314, an average signal 332 is generated after a sampling period of 8 ms 316, an average signal 334 is generated after a sampling period of 16 ms 318, an average signal 336 is generated after a sampling period of 32 ms 320, an average signal 338 is generated after a sampling period of 64 ms 322, and an average signal 340 is generated after a sampling period of 128 ms 324. The completion time 342 is the cumulative time taken for the FOC process to complete, which is the starting time 302 plus the discharge time 306, plus the cumulative duration of the sampling periods (256 ms for the embodiment depicted in FIG. 3) during the FOC process.

After the FOC process has completed, the output signal 304 begins Phase A of the slow offset compensation (“SOC”) process. Unlike in the FOC process, the sampling periods in Phase A of the SOC process are fixed (i.e., fixed sampling rate) and the averaging periods are fixed as well (i.e., a fixed averaging rate). The fixed value for the sampling period and averaging can be any positive value. In the embodiment depicted in FIG. 3, a period of 256 ms 344a, 344b is utilized for both the sampling period and averaging period, although in embodiments the sampling period and averaging period can change or can even be different each other. The output signal 304 is averaged during each consecutive sampling period to generate an average signal 346a, 346b. Although the FOC stage is not depicted and described as being repeated, in some embodiments FOC may be performed again during operations such as periodically or where an operating condition of the sensor or end use device has changed (e.g., where the offset compensation value has an unlikely value in terms of absolute value, relative value, or rate of change), which in turn may require recalibration and fast sensing of the offset.

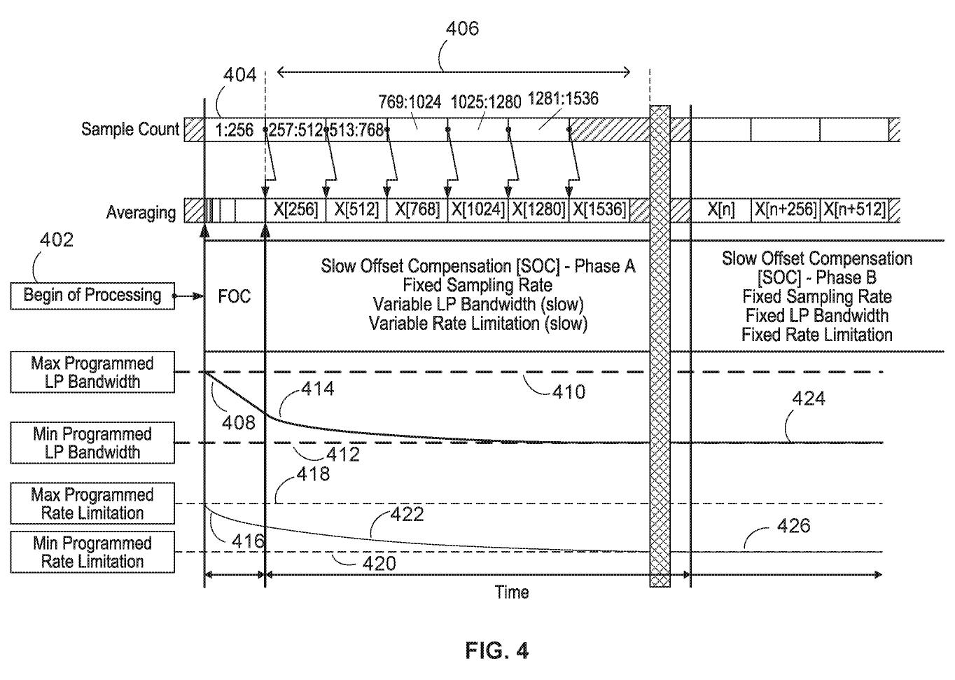

FIG. 4 depicts an exemplary timing diagram of dynamic bias compensation in accordance with an embodiment of the present disclosure. At starting time 402, signals generated by the MEMS sensor enter the FOC process. The total sample count for the FOC process 404 is 256 sample signals. During the FOC process, however, the averaging occurs at different rates. As time passes, the averaging occurs over an increasing number of samples. The low pass filter bandwidth 408 (e.g., of low pass filter 234) decreases as time passes, but does not exceed the maximum programmed bandwidth 410 or fall below the minimum programmed bandwidth 412. Similarly, the rate limitation 416 (e.g., of rate limiter 238) decreases as time passes and more samples are averaged, but does not exceed the maximum programmed rate limitation 418 or fall below the minimum programmed rate limitation 420. Once 256 sample signals have been processed by FOC, then Phase A of the SOC process may begin. During Phase A of the SOC stage both the sampling period and the averaging period of the DBC system can be fixed. In an example, the sampling period and the averaging period are the same during SOC Phase A. Phase A low pass bandwidth 414 decreases at a much slower rate, compared to the low pass filter bandwidth 408, until it reaches the minimum programmed bandwidth 412 at the end of Phase A of the SOC process. Additionally, the Phase A SOC rate limitation 422 continues to slowly decrease until it reaches the minimum programmed rate limitation 420 at the end of Phase A of the SOC process. Once such rate limitation and bandwidth levels are reached, then Phase B of the SOC process may begin, whereby the output signal is averaged based on a fixed sampling rate and a fixed averaging rate. In an example, the fixed sampling rate during Phase A can be the same as the fixed sampling rate during Phase B, while the fixed averaging rate during Phase B can be a fixed integer multiple (e.g., twice) the fixed averaging rate during Phase A. The Phase B SOC bandwidth 424 and the Phase B SOC rate limitation 426 are also fixed at their respective final values.

The low pass filter bandwidth 408 decreases during the FOC process. In some embodiments it may start at the maximum programmed bandwidth 410. This maximum value may be programmed into the FOC circuit using a register, ASIC, or any other method of programming. As time passes, the low pass filter bandwidth 408 steadily decreases at a rate that may also be programmed before initiating the FOC process. Generally, the rate decreases as an exponential decay, but in some cases it may be relatively linear or other suitable rates of decay. During the FOC process, the FOC bandwidth 408 never reaches the minimum programmed bandwidth 412. This minimum value may be programmed into the FOC circuit using a register, ASIC, or any other method of programming.

The FOC rate limitation 416 decreases during the FOC process. In some embodiments it may start at the maximum programmed rate limitation 418. This maximum value may be programmed into the FOC circuit using a register, ASIC, or any other method of programming. At the start, the FOC rate limitation 408 decreases rapidly and then gradually declines, at a rate that may also be programmed before initiating the FOC process. Generally at the start, the rate decreases exponentially, but in some cases it may be a linear decay or other suitable rates of decay. In some embodiments, during the FOC process, the rate limitation 420 may not completely reach this minimum value. This minimum value may be programmed into the FOC circuit using a register, ASIC, or any other method of programming.

Once the sampling rate becomes fixed, the FOC process concludes and Phase A of the SOC process begins. During Phase A of the SOC process, the number of samples averaged per sampling period is constant, but the Phase A low pass filter bandwidth 414 still remains variable. Over the entire Phase A of the SOC process, the Phase A low pass filter bandwidth 414 decreases until it reaches the minimum programmed bandwidth 412. In some embodiments, the Phase A low pass filter bandwidth 414 may not completely reach this minimum value.

Similarly, during Phase A of the SOC process, the Phase A SOC rate limitation 422 remains variable. The Phase A SOC rate limitation 422 continues to decrease gradually and slowly at the same rate of decay as the FOC rate limitation 416. In some embodiments, however, the rate of decay of the Phase A rate limitation 422 may not continue decreasing at the same rate of decay as the FOC rate limitation 416. Over the entire Phase A of the SOC process, the Phase A SOC rate limitation 422 decreases until it reaches the minimum programmed rate limitation 420. In some embodiments, the Phase A SOC rate limitation 422 may not completely reach this minimum value.

Once the Phase A SOC bandwidth 414 and Phase A SOC rate limitation 422 reach (or almost reach) their minimum respective values, then Phase A of the SOC process concludes, and Phase B of the SOC process begins. During this phase, not only do the sampling period and averaging period remain fixed, but so does the Phase B low pass filter bandwidth 424 and the Phase B SOC rate limitation 426. These values may be at their respective programmed minimum values or at values close to their respective programmed minimum values. Note that upon reinitiating or significantly perturbing the offset compensation process (e.g., resetting the MEMS sensor), the entire FOC and SOC processes may need to be restarted (from starting time 402). For example, in cases where external factors (e.g., elevated temperatures) are detrimental to the functioning of the MEMS sensor, repeating the FOC and SOC processes may be desirable.

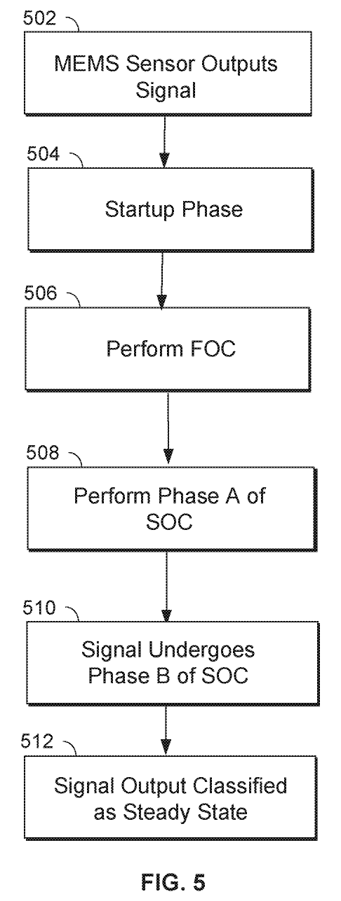

FIG. 5 depicts exemplary steps for performing dynamic bias compensation in accordance with an embodiment of the present disclosure. Although particular steps are depicted in a certain order for FIG. 5, steps may be removed, modified, or substituted, and additional steps may be added in certain embodiments, and in some embodiments, the order of certain steps may be modified.

Processing starts at step 502, where the MEMS sensor (e.g., a MEMS inertial sensor) outputs a signal such as a signal representative of linear acceleration in a particular direction. The signal undergoes processing and filtering operations to generate an output signal utilized for determining an offset and linear acceleration. Processing may continue to step 504.

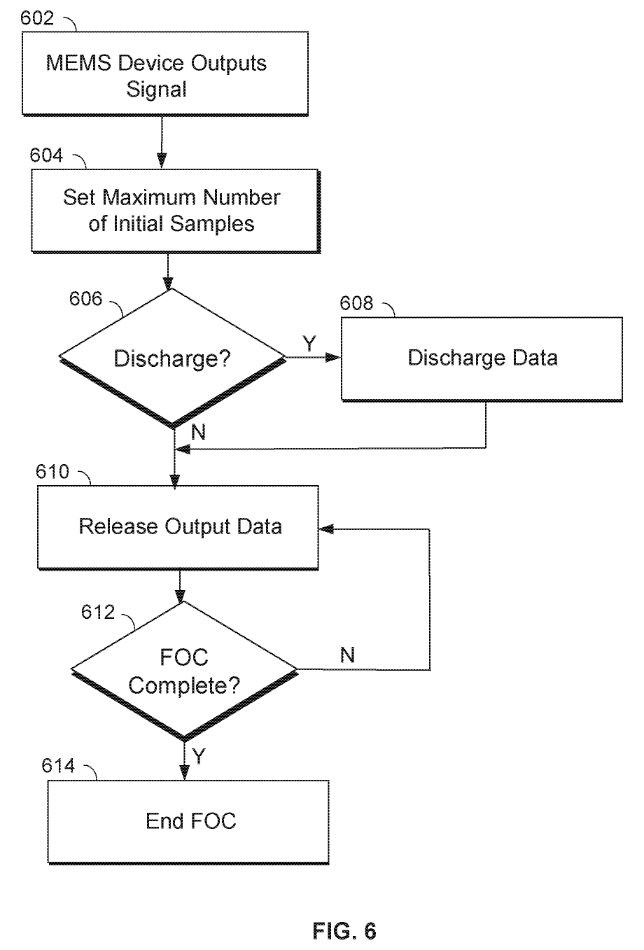

At step 504, a startup phase is performed. The received signal is analyzed as initial data is received to determine whether the received output signal is suitable for being used to generate an offset compensation signal as described herein and further described at steps 606 – 610 of FIG. 6. Once the startup phase is completed, processing continues to step 506.

Fast offset compensation is performed at step 506, as described further in FIG. 6. A set number of samples may be discharged if particular thresholds are not met (e.g., amplitude value) in order to mitigate processing initial aberrant signals. Once processing of samples begins, the number of signals used to determine the offset (e.g., by filtering and averaging as described herein steadily increases. Once a maximum number of signals to be averaged is reached or other criteria are reached, processing may continue to step 508.

Phase A of the slow offset compensation is performed at step 508. At this step, the signal may be further converted for more effective modulation in later steps. Downsampling occurs such that the data rate decreases (e.g., 16 kHz to 1 kHz). During Phase A of SOC, characteristics of the dynamic bias compensation system may be variable, such as for the rate limiter and low pass filter may all have variable parameters. In some embodiments, both the sampling period and the averaging period can be fixed. Phase A of SOC may continue for a period of time or until certain criteria are reached, after which processing may continue to step 510.

Phase B of SOC is performed at step 510. The sampling rate and parameters (e.g., bandwidth, rate limiter slope) of the various components within the DBC system are fixed. The output signal is consistently modulated under fixed parameters. Processing may continue to step 512.

Without further adjustments to the SOC circuit, the signal output is classified as steady state at step 512. After a period of time, dynamic modifications of the processing parameters are no longer required and offset compensation now proceeds at a constant rate. Note that upon reinitiating or significantly perturbing the offset compensation process (e.g., resetting the MEMS sensor), the entire process may need to be restarted from step 502. For example, in cases where external factors (e.g., elevated temperatures) are detrimental to the functioning of the MEMS sensor, repeating the offset compensation process may be desirable.

FIG. 6 depicts exemplary steps of a startup phase and a fast offset compensation phase of dynamic bias compensation in accordance with an embodiment of the present disclosure. Although particular steps are depicted in a certain order for FIG. 6, steps may be removed, modified, or substituted, and additional steps may be added in certain embodiments, and in some embodiments, the order of certain steps may be modified.

Processing starts at step 602, where the MEMS sensor (e.g., a MEMS inertial sensor) outputs a signal such as a signal representative of linear acceleration in a particular direction. The signal undergoes processing and filtering operations to generate an output signal utilized for determining an offset and linear acceleration. Processing may continue to step 604.

The maximum number of output signal samples to be averaged is set at step 604. The maximum number of signal samples (N_{Max}) follows the formula: N_{Max} = 2^{k}, where “k” is any whole number. For example, if “k” was equal to 4, then the first maximum number of samples to be averaged would be 16. This may be programmed within a particular register interface within the FOC circuit before startup. Once an Nₘₐₓ value is chosen, processing may continue to step 606.

A startup phase during which the decision to discharge any initial output data from the MEMS sensor is implemented at steps 606 through 610. At step 606, the first output signal (or plurality of output signals) from the MEMS sensor is erratic or too dynamic, then it may be desirable to discharge some of that initial data before starting the FOC process. For example, if the output signal is not within predefined limits of amplitude and signal derivative, then a discharge time may be implemented to allow time for a less dynamic signal to be outputted by the MEMS sensor. The decision to discharge or not may be programmed within a particular register interface within the FOC circuit before operation of the DBC system. If an initial signal discharge is not to be performed, processing proceeds to step 610. If an initial signal discharge is to be performed, processing proceeds to step 608.

At step 608, initial output data from the MEMS sensor is discharged. The amount and/or duration of discharge can be time-based (e.g., 50 ms), signal characteristic-based (e.g., amplitude threshold), signal amount-based (e.g., 50 signal samples), or any other parameter or combination of parameters such that the FOC circuit can still operate within its functional bounds. The amount and/or duration of discharge may be programmed within a particular register interface within the DBC system (or supplementary circuit) before activation of the DBC system or MEMS sensor. For example, the discharge will not finish (i.e., FOC will not start) until particular conditions are met such as two consecutive signals having a characteristic amplitude. Once the discharge process is complete, processing may continue to step 610.

At step 610, the output signal from the MEMS sensor is released into the FOC phase. The number of signal samples (Nₖ) to be averaged proceeds using the formula: Nₖ = 2^{k}, where “k” starts at 0 and generally increases incrementally by 1 (i.e., 0, 1, 2, 3, 4…). For example, if “k” is equal to 2, then the number of signal samples to be averaged at that point is 4. Note that in some embodiments, this formula may be slightly altered or the value of “k” may increase at different rates (e.g., “k” is only even numbers). After a single set of output signals from the MEMS sensor has been averaged by the FOC circuit, processing may continue to step 612.

At step 612, it is determined if the maximum number of initial samples to average has been reached. N_{Max} was calculated and/or predefined in step 604. If Nₖ equals N_{Max}, then processing may continue to step 614. If Nₖ does not equal N_{Max}, then processing may continue back to step 610, where the process occurs again, but with the value of “k” increasing by the next increment.

Once the maximum number of initial samples to average (N_{Max}) has been reached, then FOC is suspended at step 614. The FOC process is now complete and the output signal proceeds to other portions of the circuit (e.g., Phase A of SOC). Note that in some embodiments, the offset compensation process may end here (i.e., only FOC processing was performed), while in other embodiments, FOC processing may be repeated to ensure offset compensation consistency and/or monitoring. Further, upon reinitiating or significantly perturbing the fast offset compensation process (e.g., resetting the MEMS sensor), the entire FOC process may need to be restarted from step 602. For example, in cases where external factors (e.g., elevated temperatures) are detrimental to the functioning of the MEMS sensor, repeating the FOC process may be desirable.

The foregoing description includes exemplary embodiments in accordance with the present disclosure. These examples are provided for purposes of illustration only, and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. A method for dynamically compensating for offset in a microelectromechanical system (MEMS) sensor, comprising:
receiving an output signal based on a movement of a proof mass of the MEMS sensor in response to a force;
monitoring the output signal for at least one signal characteristic, wherein the output signal is discarded until the at least one signal characteristic is identified by the monitoring;
processing, once the at least one signal characteristic has been identified, the output signal to determine an offset compensation signal that compensates an offset in the output signal, wherein the processing comprises:
performing a first filtering of the output signal;
averaging a first set of samples of the first filtered output signal over an initial sampling period of a plurality of sampling periods to generate the offset compensation signal for the initial sampling period;
increasing from the initial sampling period to a first sampling period;
averaging a second set of samples of the first filtered output signal over the first sampling period to generate the offset compensation signal for the first sampling period;
repeating the increasing of the sampling period during a startup phase;
averaging an additional set of samples of the first filtered output signal over each increased sampling period to generate the offset compensation signal for each increased sampling period;
determining that the startup phase is complete;
sampling the first filtered output signal over a fixed sampling period once the startup phase is complete to generate a plurality of fixed sample sets; and
averaging each of the fixed sample sets over a fixed averaging period once the startup phase is complete to generate the offset compensation signal for each fixed averaging period, wherein the fixed averaging period is greater than or equal to a longest sampling period of the increased sampling periods, and wherein the fixed sampling period is lower than or equal to the fixed averaging period.

2. The method of claim 1, wherein the identification of the at least one signal characteristic comprises an amplitude of the output signal not exceeding a predefined limit.

3. The method of claim 1, wherein the identification of the at least one signal characteristic comprises the output signal derivative not exceeding a predefined limit.

4. The method of claim 1, wherein the processing once the at least one signal characteristic has been identified comprises an initiation of the startup phase.

5. The method of claim 1, further comprising performing a second filtering, wherein the offset compensation signal is further based on the second filtering applying a low pass filter to the averaged sample sets.

6. The method of claim 5, further comprising dynamically modifying the second filtering, wherein the dynamically modifying comprises adjusting a bandwidth of the low pass filter for different sampling periods of the plurality of sampling periods.

7. The method of claim 1, wherein each increase of the sampling period comprises doubling of an immediately prior sampling period.

8. The method of claim 7, wherein an increased period for the averaging associated with each increase of the sampling period is double of an immediately prior period for averaging an immediately prior sample set.

9. The method of claim 7, wherein the fixed sampling period is a multiple of a longest sampling period of the increased sampling periods, wherein the multiple of the longest sampling period is two, wherein the fixed averaging period is a multiple of a longest averaging period associated with the increased sampling periods, and wherein the multiple of the longest averaging period is two.

10. The method of claim 1, wherein the first filtering of the output signal comprises filtering the output signal to reduce a vibration component within the output signal, and wherein the first filtering of the output signal to reduce the vibration component within the output signal comprises applying a low pass filter to the output signal.

11. The method of claim 10, wherein the first filtering of the output signal further comprises modifying the output signal to reduce a shock component within the output signal, and wherein modifying the output signal to reduce the shock component comprises limiting an amplitude of the output signal whenever it is above a predefined amplitude threshold.

12. The method of claim 11, wherein limiting the amplitude of the output signal comprises clamping an amplitude of the output signal to the predefined amplitude threshold or substituting the output signal with a zero signal.

13. The method of claim 11, further comprising dynamically modifying the first filtering, wherein the dynamically modifying comprises:
modifying the predefined amplitude threshold for different sampling periods of the plurality of sampling periods; and
adjusting a bandwidth of the low pass filter for different sampling periods of the plurality of sampling periods.

14. The method of claim 13, wherein the modifying and the adjusting correspond to a plurality of the increased sampling periods, and wherein the modifying and the adjusting are performed during at least some of the fixed sampling periods.

15. The method of claim 14, further comprising:
determining whether the startup phase has elapsed; and
based on the startup phase being elapsed, fixing the predefined amplitude threshold and the bandwidth for additional fixed sampling periods.

16. The method of claim 1, further comprising:
adjusting, by a rate limiter, the offset compensation signal such that the offset compensation signal does not change by more than a rate; and
downsampling the output signal from a first data rate prior to the processing.

17. The method of claim 16, further comprising, after the processing and before the compensating, increasing a data rate of the offset compensation signal to correspond to the first data rate.

18. The method of claim 1, wherein the output signal is based on one or more processing operations applied to a measured signal corresponding to a capacitance that is based on the movement of the proof mass, and wherein the processing operations comprise one or more of a capacitance to voltage converter, an integrator, a modification of a gain, a modification of scaling, a low pass filter, or a band pass filter.

19. A method for removing offset from an output signal of a microelectromechanical system (MEMS) sensor, comprising:
monitoring an output signal from the MEMS sensor to determine whether to start a fast offset compensation stage of operation, wherein an offset compensation signal that is used to compensate an offset in the output signal is not generated prior to the start of the fast offset compensation stage of operation;
generating the offset compensation signal, during the fast offset compensation stage of operation, based on an increasing sampling period and an increasing averaging period;
changing from the fast offset compensation stage of operation to a first slow offset compensation stage of operation;
generating the offset compensation signal, during the first slow offset compensation stage of operation, based on a first fixed sampling period and a first fixed averaging period;
changing from the first slow offset compensation stage of operation to a second slow offset compensation stage of operation; and
generating the offset compensation signal, during the second slow offset compensation stage of operation, based on a second fixed sampling period and a second fixed averaging period, wherein the second fixed averaging period is different than the first fixed averaging period.

20. A system for removing offset from an output signal of a (MEMS) sensor, comprising:
amplitude limiting circuitry coupled to receive the output signal from the MEMS sensor and to limit an amplitude of the output signal to output an amplitude-limited signal;
a filter coupled to the amplitude limiting circuitry to receive the amplitude-limited signal, wherein the filter removes a samples that are not within a pass band of the filter to output a filtered signal;
averaging circuitry coupled to the filter to receive the filtered signal, wherein the averaging circuitry outputs an averaged signal based on a sampling period and an averaging period;
processing circuitry coupled to the averaging circuitry to process the averaged signal to generate an offset compensation signal that is suitable for removing the offset from the output signal; and
a bandwidth controller configured to modify a bandwidth of the filter, the sampling period, and the averaging period, wherein each of the bandwidth, the sampling period, and the averaging period are modified during an initial fast offset compensation stage of operation, and wherein the bandwidth, the sampling period, and the averaging period become fixed during at least a portion of a slow offset compensation stage that occurs after completion of the initial fast offset compensation stage.
